(19) United States
(12) Patent Application Publication
(10) Pub. No.: US 2022/0087034 A1
(43) Pub. Date: Mar. 17, 2022

(54) METHOD OF MANUFACTURING CIRCUIT BOARD STRUCTURE

(71) Applicants: AZOTEK CO., LTD., Taoyuan City (TW); IIDA ELECTRONICS CO., LTD., TAIPEI (TW)

(72) Inventors: Hung-Jung LEE, Taoyuan City (TW); Shang-Ming FANG, Taipei (TW)

(21) Appl. No.: 17/444,672

(22) Filed: Aug. 9, 2021

(30) Foreign Application Priority Data
Sep. 17, 2020 (TW) 109132129

(51) Int. Cl. H05K 3/40; H05K 3/46; G03F 7/09

(52) U.S. Cl. CPC H05K 3/4038; H05K 3/4673; H05K 2203/0588; H05K 2203/0551; G03F 7/094

(57) ABSTRACT

A method of manufacturing circuit board structure includes operations below. First, a first substrate is provided. A first wire structure is formed on the first substrate, in which the first wire structure includes a first wire having a first height and a second wire having a second height, and the first height is greater than the second height. A liquid crystal polymer layer is then formed on the first substrate and covers the first wire structure.

### CROSS-REFERENCE TO RELATED APPLICATION

This application claims priority to Taiwan Application Serial Number 109132129, filed Sep. 17, 2020, which is herein incorporated by reference in its entirety.

### BACKGROUND

### Field of Invention

The present invention relates to a method of manufacturing a circuit board structure.

### Description of Related Art

In general, electronic components such as a microprocessor and an antenna are disposed on a circuit board of a communication device. The electronic components are connected to each other by circuits of the circuit board to transfer data. However, since the amount of data to be transferred between each electronic component is different, the number of circuits between the electronic components will also be different. That is to say, the distribution of wiring density on the circuit board is not uniform. For example, the microprocessor is mainly used to handle most of the data transfer and control actions. Therefore, the wiring density of the circuit area of the microprocessor is relatively higher than other electronic components in order to be able to process a large amount of data. The wiring density of the antenna area is relatively low.

With the increase in the functions of microprocessors and the variety of electronic components on circuit boards, the number of circuits between microprocessors or other electronic components has increased to facilitate the processing of more data, resulting in increased wiring density. However, due to the size of the circuit area on the circuit board is fixed, when the circuit density exceeds a certain limit, more layers of circuit boards must be used to form the circuit layout. However, high wiring density is not required for the entire circuit board. If a circuit board with a larger number of layers is used, such as a six-layered board or an eight-layered board, the manufacturing cost will increase and the manufacturing process will be more complicated.

### SUMMARY

In view of the above, a purpose of the present disclosure is to provide a method of manufacturing a circuit board structure that can solve the above problems.

To achieve the above purpose, an aspect of the present disclosure provides a method of manufacturing a circuit board structure including the following operations. (i) First, a first substrate is provided. (ii) Next, a first wire structure is formed on the first substrate. The first wire structure includes a first wire having a first height and a second wire having a second height, and the first height is greater than the second height. (iii) A liquid crystal polymer layer is then formed on the first substrate and covers the first wire structure.

According to one embodiment of the present disclosure, the method further includes forming a conductive layer between the first substrate and the first wire structure.

According to one embodiment of the present disclosure, the conductive layer is a patterned conductive layer or a conductive layer covering an entire upper surface of the first substrate.

According to one embodiment of the present disclosure, the operation (ii) includes forming a first photoresist covering the first substrate; forming a first opening and a second opening to expose a portion of the first substrate; filling the first opening and the second opening with a first conductive material; forming a second photoresist covering the first photoresist and the first conductive material; forming a third opening to expose the first conductive material filled in the first opening; filling the third opening with a second conductive material, in which the second conductive material is in direct contact with the first conductive material in the first opening; and removing the first photoresist and the second photoresist to form the first wire and the second wire.

According to one embodiment of the present disclosure, the first photoresist is a dry film photoresist or a liquid photoresist.

According to one embodiment of the present disclosure, the second photoresist is a dry film photoresist or a liquid photoresist.

According to one embodiment of the present disclosure, the first wire structure further includes a third wire having a third height, the third height is smaller than the first height and greater than the second height.

According to one embodiment of the present disclosure, the operation (ii) includes forming a first photoresist covering the first substrate; forming a first opening, a second opening, and a third opening to expose a portion of the first substrate; filling the first opening, the second opening, and the third opening with a first conductive material; forming a second photoresist covering the first photoresist and the first conductive material; forming a fourth opening and a fifth opening to respectively expose the first conductive material filled in the first opening and the first conductive material filled in the second opening; filling the fourth opening and the fifth opening with a second conductive material, in which the second conductive material is in direct contact with the first conductive material in the first opening and the second opening; forming a third photoresist covering the second photoresist and the second conductive material; forming a sixth opening to expose the second conductive material filled in the fourth opening; filling the sixth opening with a third conductive material, in which the third conductive material is in direct contact with the second conductive material in the fourth opening; and removing the first photoresist, the second photoresist, and the third photoresist to form the first wire, the second wire, and the third wire.

According to one embodiment of the present disclosure, the method further includes the following operations. (iv) A second substrate is provided. (v) A second wire structure is formed on the second substrate, in which the second wire structure comprises a fourth wire having a fourth height. (vi) The second substrate is coupled to the first substrate so that the fourth wire is embedded in the liquid crystal polymer layer and in direct contact with the second wire.

According to one embodiment of the present disclosure, a sum of the fourth height and the second height is substantially equal to a thickness of the liquid crystal polymer layer.

According to one embodiment of the present disclosure, the operation (vi) is performed at a temperature between a liquid crystal polymer glass transition temperature and a liquid crystal polymer melting point.

Another aspect of the present disclosure provides a method of manufacturing a circuit board structure including the following operations. (i) First, a first substrate is provided. (ii) Next, a first wire structure is formed on the first substrate, in which the first wire structure includes a first wire having a first height, a second wire having a second height, and a third wire having a third height. The first height is greater than the second height. The third height is smaller than the first height and greater than the second height. (iii) A liquid crystal polymer layer is then formed on the first substrate and covers the first wire structure. (iv) A second substrate is provided. (v) A second wire structure is formed on the second substrate, in which the second wire structure comprises a fourth wire having a fourth height and a fifth wire having a fifth height. (vi) The second substrate is coupled to the first substrate so that the fourth wire and the fifth wire are embedded in the liquid crystal polymer layer and respectively in direct contact with the second wire and the third wire.

According to one embodiment of the present disclosure, a sum of the fourth height and the second height is substantially equal to a thickness of the liquid crystal polymer layer.

According to one embodiment of the present disclosure, a sum of the fifth height and the third height is substantially equal to a thickness of the liquid crystal polymer layer.

According to one embodiment of the present disclosure, the operation (vi) is performed at a temperature between a liquid crystal polymer glass transition temperature and a liquid crystal polymer melting point.

### BRIEF DESCRIPTION OF THE DRAWINGS

The invention can be more fully understood by reading the following detailed description of the embodiment, with reference made to the accompanying drawings as follows:

FIG. 1 is a flow chart of a method of manufacturing a circuit board structure according to one embodiment of the present disclosure.

FIGS. 2, 3, 13, 14, 15, and 16 are schematic cross-sectional views of each process stage in manufacturing a circuit board structure according to one embodiment of the present disclosure.

FIGS. 4, 5, 6, 7A, 7B, 8A, 8B, 9A, 9B, 10, 11, and 12 are schematic cross-sectional views of each process stage in manufacturing a circuit board structure according to various embodiments of the present disclosure.

FIG. 17 is a schematic cross-sectional view of a certain part of the conventional circuit board structure according to one comparative example of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. The embodiments disclosed below may be combined or substituted with each other under beneficial circumstances, and other embodiments may also be added to an embodiment without further description.

In the following description, certain specific details are set forth in order to provide a thorough understanding of various embodiments of the disclosure. However, one skilled in the art will understand that the disclosure may be practiced without these specific details. Furthermore, for simplifying the drawings, some of the conventional structures and elements are shown with schematic illustrations.

It is to be noticed that the term “comprising”, used in the claims, should not be interpreted as being restricted to the means listed thereafter; it does not exclude other elements or steps. It is thus to be interpreted as specifying the presence of the stated features, integers, steps or components as referred to, but does not preclude the presence or addition of one or more other features, integers, steps or components, or groups thereof. Thus, the scope of the expression “a device comprising means A and B” should not be limited to a device consisted only of components A and B.

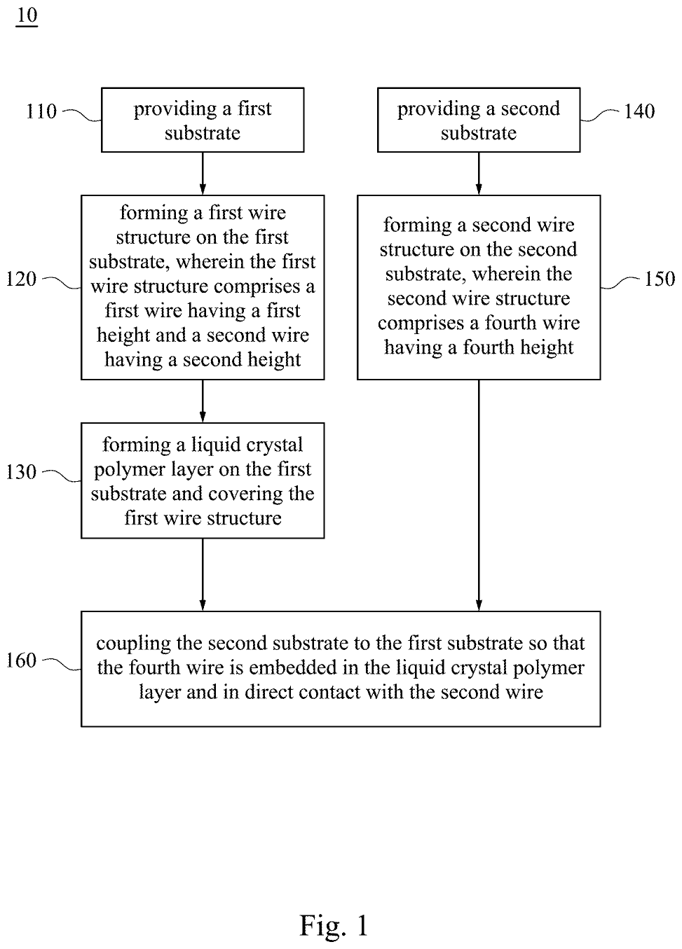

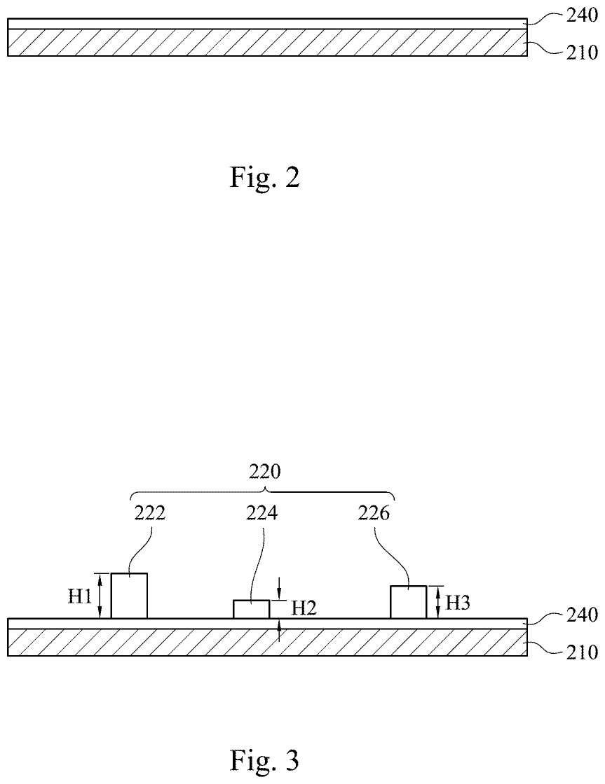

FIG. 1 is a flow chart of a method 10 of manufacturing a circuit board structure according to one embodiment of the present disclosure. FIGS. 2-13 are schematic cross-sectional views of each process stage in the method 10 of manufacturing the circuit board structure A according to one embodiment of the present disclosure. It is understood that additional operations may be implemented before, during, and after the method 10, and some of the operations may be replaced, eliminated, or moved around for additional embodiments of the method 10. The method 10 is only an exemplary embodiment, and is not intended to limit the present invention beyond what is explicitly recited in the claims. The method 10 of manufacturing the circuit board structure A at least includes operation 110, operation 120, and operation 130.

In operation 110, a first substrate 210 is provided, as shown in FIG. 2. In some embodiments, the first substrate 210 is a soft board including polyimide (PI), polytetrafluoroethylene (PTFE), liquid crystal polymer (LCP), and a combination thereof. In other words, the first substrate 210 is flexible.

In operation 120, a first wire structure 220 is formed on the first substrate 210, as shown in FIG. 3. To be specific, the first wire structure 220 includes a first wire 222 having a first height H1 and a second wire 224 having a second height H2, and the first height H1 is greater than the second height H2. In various embodiments, the first wire structure 220 may include copper, aluminum, iron, silver, palladium, nickel, chromium, molybdenum, tungsten, zinc, manganese, cobalt, gold, tin, lead, stainless steel, or an alloy of at least two of the above metal materials.

In various embodiments, a conductive layer 240 may be formed between the first substrate 210 and the first wire structure 220, as shown in FIG. 2. More specifically, the conductive layer 240 may be a patterned conductive layer or a conductive layer covering an entire upper surface of the first substrate. For example, the entire conductive layer may include copper foil, aluminum foil, silver foil, tin foil, and/or gold foil. For example, the patterned conductive layer is formed by etching the entire conductive layer. The following operations and embodiments may include the conductive layer 240 or include no conductive layer 240, which are only an example illustrated in conjunction with the drawings.

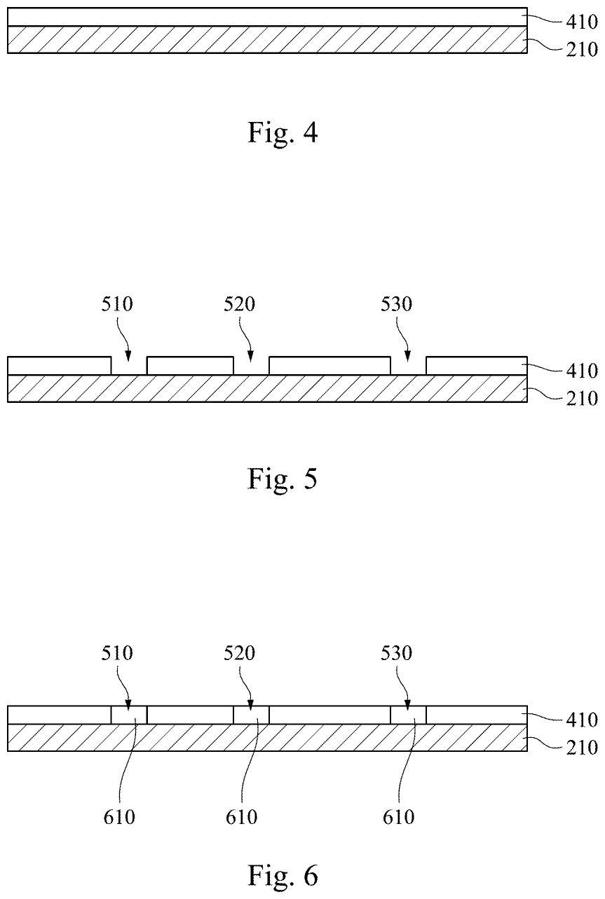

FIGS. 4, 5, 6, 7A, 8A, and 9A are schematic cross-sectional views of each process stage in manufacturing the wire structure 220 according to one embodiment of the present disclosure. In various embodiments, the first wire structure 220 having wires with different height may be formed by depositing conductive materials multiple times. The detailed manufacturing process is as below. Step (a): a photoresist 410 is first formed to cover the first substrate 210, as shown in FIG. 4. For example, the photoresist 410 may be a dry film photoresist or a liquid photoresist.

More specifically, the dry film photoresist may include polyester acrylates, which has a repeating unit structure as below:

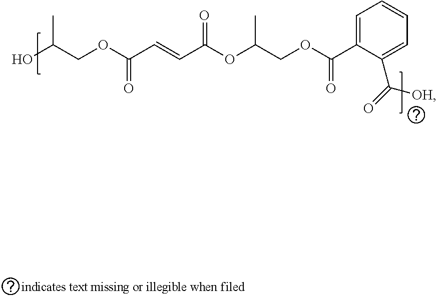

polyether acrylates, which has a repeating unit structure as below:

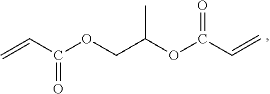

polyurethane acrylates, which has a repeating unit structure as below:

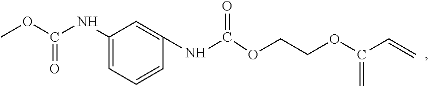

or epoxy acrylates, which has a repeating unit structure as below:

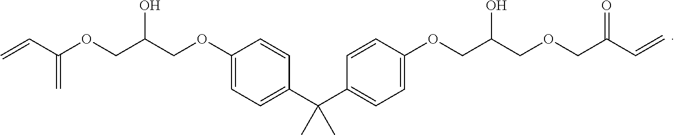

More specifically, the liquid photoresist may include alicyclic polymers, poly(methyl methacrylate) (PMMA), which has a repeating unit structure as below:

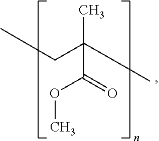

poly(acrylic acid), which has a repeating unit structure as below:

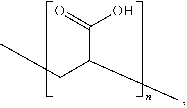

polynorbornene, which has a repeating unit structure as below:

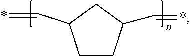

poly(vinyl naphthalene), which has a repeating unit structure as below:

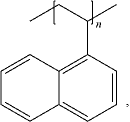

poly(norbornene-alt-maleic anhydride), which has a repeating unit structure as below:

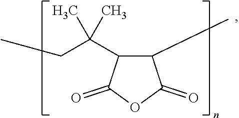

poly(tetrafluoroethylene), which has a repeating unit structure as below:

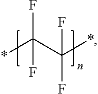

poly(methyl trifluoromethyl acrylate), which has a repeating unit structure as below:

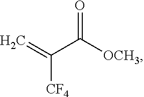

poly(styrene), which has a repeating unit structure as below:

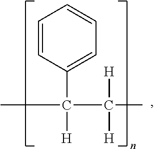

or poly(fluorostyrene) or poly(hexafluoroisopropanolstyrene), which has a repeating unit structure as below:

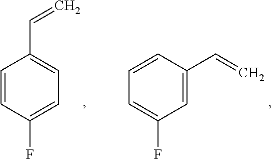

In addition, in some embodiments, the liquid photoresist may further include poly(4-hydroxystyrene), poly(t-butyl acrylate), poly(norbornene methylene hexafluoro isopropanol), poly(norbornene hexafluoro alcohol-co-norbornene hexafluoro alcohol tbutoxycarbonyl), poly(norbornene hexafluoro alcohol-co-norbornene hexafluoro alcohol acetal), poly(1,1,2,3,3-pentafluoro, 4-trifluoromethyl-4-hydroxy1,6-heptadiene) (PFOP), poly(tert-butyl[2,2,2-trifluoro-1-trifluoromethyl-1-(4-vinyl-phenyl)ethoxy]-acetate), poly(1-(2,2,2-trifluoro-1-methoxymethoxy-1-trifluoromethylethyl)-4-vinyl benzene), poly(1-[1-(tert-butoxymethoxy)-2,2,2-trifluoro-1-trifluoromethylethyl]-4-vinylbenzene), poly(1-[1-(tert-butoxycarbonyl)-2,2,2-trifluoro-1-trifluoromethylethyl]-4-vinylbenzene), or poly(2-[4-(2-hydroxyhexafluoroisopropyl) cyclohexane]hexafluoroisopropyl acrylate).

Step (b): next, the photoresist 410 is patterned, thereby forming an opening 510 and an opening 520 to expose a portion of the first substrate 210, as shown in FIG. 5. For example, the patterned photoresist 410 may be completed by photolithography process.

Step (c): the opening 510 and the opening 520 are filled with a conductive material 610, as shown in FIG. 6. For example, step (c) may be completed by suitable processes such as electroplating, electroless plating, physical vapor deposition, chemical vapor deposition, atomic layer deposition, and the like. For example, the conductive material 610 may include copper, aluminum, iron, silver, palladium, nickel, chromium, molybdenum, tungsten, zinc, manganese, cobalt, gold, tin, lead, stainless steel, or an alloy of at least two of the above metal materials.

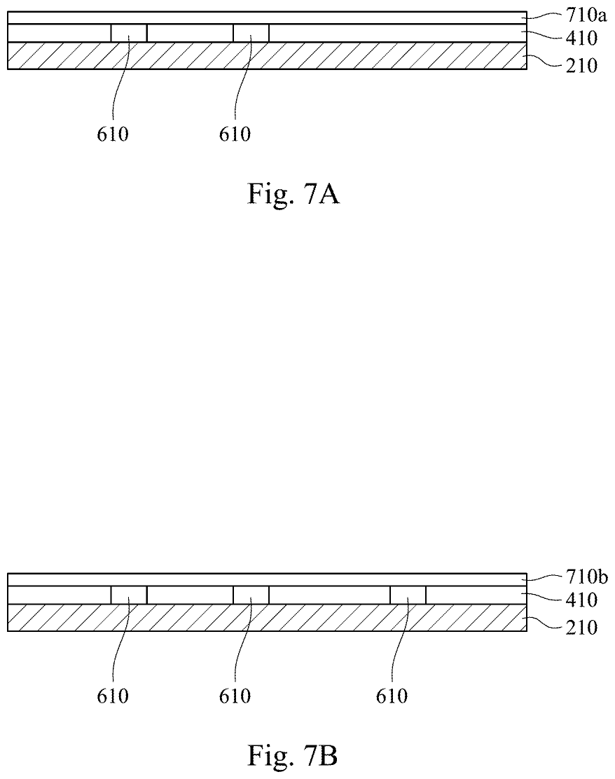

Step (d): a photoresist 710a is formed to cover the photoresist 410 and the conductive material 610, as shown in FIG. 7A. In various embodiments, the material of the photoresist 710a may be the same or similar to that of the photoresist 410.

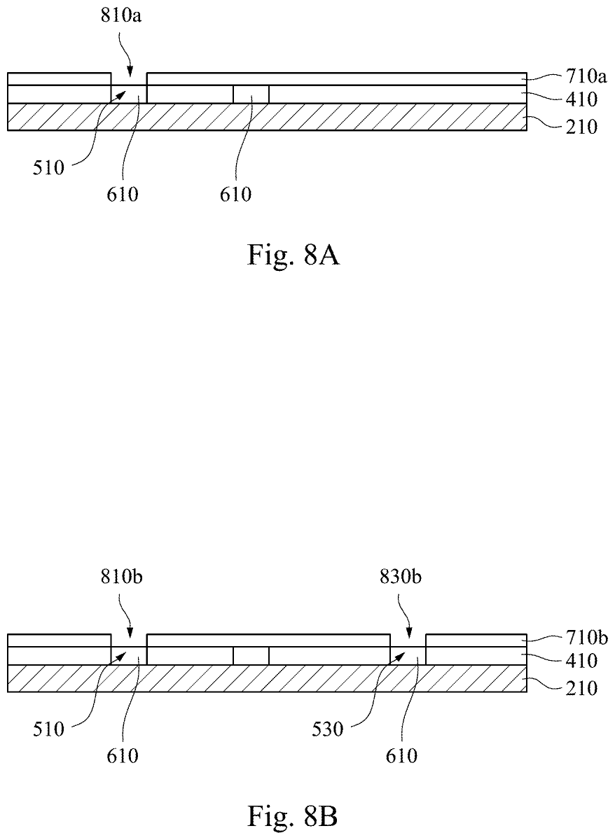

Step (e): an opening 810a is formed to expose the conductive material 610 filled in opening 510, as shown in FIG. 8A. In various embodiments, the opening 810a is substantially aligned with the opening 510. In various embodiments, a size of the opening 810a is substantially the same as that of the opening 510.

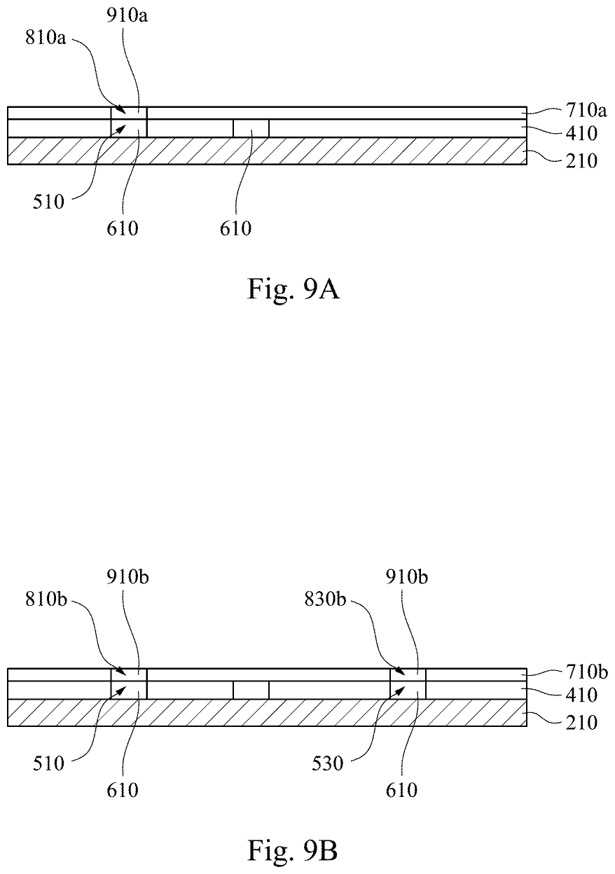

Step (f): the opening 810a is filled with a conductive material 910a, in which the conductive material 910a is in direct contact with the conductive material 610 in the opening 510, as shown in FIG. 9A. In various embodiments, the conductive material 910a may be the same as the conductive material 610.

Step (g): the photoresist 410 and the photoresist 710a are removed to form the first wire 222 and the second wire 224 as shown in FIG. 3. In various embodiments, the photoresist 410 and the photoresist 710a may be removed with a suitable photoresist stripper.

It is noted that a circuit board structure with fine wires may be produced by the method of manufacturing the wire structure 220 mentioned above. For example, the line width may be ranged from about 15 um to about 50 um, such as 20 um, 25 um, 30 um, 35 um, or 45 um. In addition, the method mentioned above can not only be used to form circuits, but also can be used to form conductive via holes, thereby avoiding the problem of dimple. The detailed content is as followings.

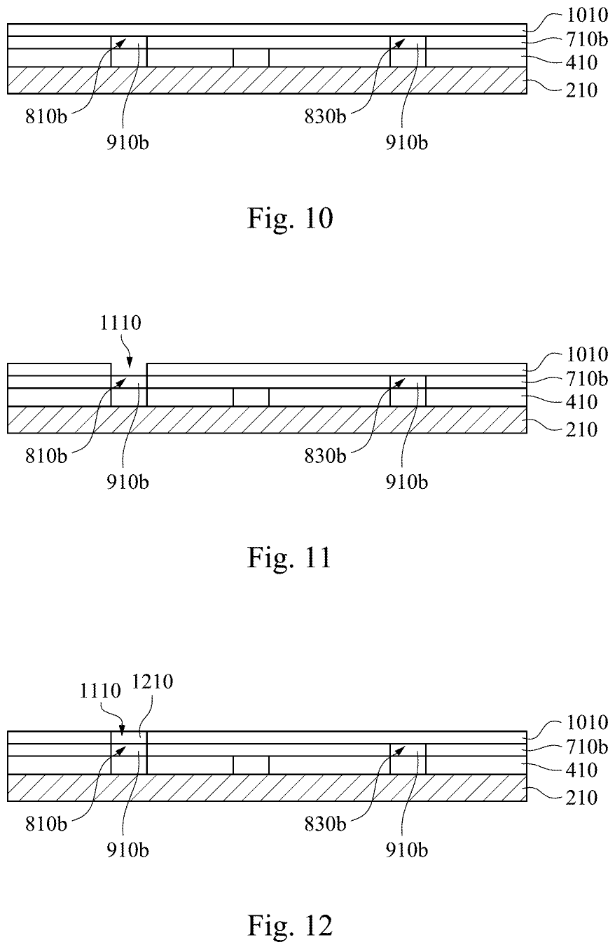

Please back to FIG. 3, in some embodiments, the first wire structure 220 may further include a third wire 226 having a third height H3, and the third height H3 is smaller than the first height H1 and greater than the second height H2. FIGS. 4, 5, 6, 7B, 8B, 9B, 10, 11, and 12 are schematic cross-sectional views of each process stage in manufacturing the wire structure 220 according to one embodiment of the present disclosure. In various embodiments, the third wire 226 having the third height H3 between the first height H1 and the second height H2 may also be formed by depositing the conductive material multiple times as described above. In this embodiment, the manufacturing process is briefly described as following. The photoresist 410 is first formed to cover the first substrate 210, as shown in FIG. 4. Next, openings 510, 520, and 530 are formed to expose a portion of the first substrate 210, as shown in FIG. 5. The openings 510, 520, and 530 are filled with the conductive material 610. A photoresist 710b is formed to cover the photoresist 410 and the conductive material 610, as shown in FIG. 7B. Openings 810b and 830b are formed to respectively expose the conductive material 610 filled in the openings 510 and 530, as shown in FIG. 8B. Openings 810b and 830b are filled with a conductive material 910b, in which the conductive material 910b is in direct contact with the conductive material 610 in the openings 510 and 530, as shown in FIG. 9B. A photoresist 1010 is formed to cover the photoresist 710b and the conductive material 910b, as shown in FIG. 10. Opening 1110 is formed to expose the conductive material 910b filled in the opening 810b, as shown in FIG. 11. Opening 1110 is filled with a conductive material 1210, in which the conductive material 1210 is in direct contact with the conductive material 910b in the opening 810b, as shown in FIG. 12. Finally, the photoresists 410, 710b, and 1010 are removed to form the first wire 222, the second wire 224, and the third wire 226 as shown in FIG. 3.

In various embodiments, the material of the photoresists 710b and 1010 are the same as that of the photoresist 410. In various embodiments, the conductive materials 910b and 1210 are the same as or similar to the conductive material 610.

It can be understood that although there are three wires having different heights illustrated in FIG. 3, those skilled in the art may design 4, 5, 6, or several wires having different heights or the same height according to requirements. Moreover, a wire structure having more wires may be formed by referring to the method of manufacturing wires as described above.

The melting point of the thermotropic liquid crystal polymer described below is a temperature at which the thermotropic liquid crystal polymer transfers from a solid state to a liquid crystal state having fluidity.

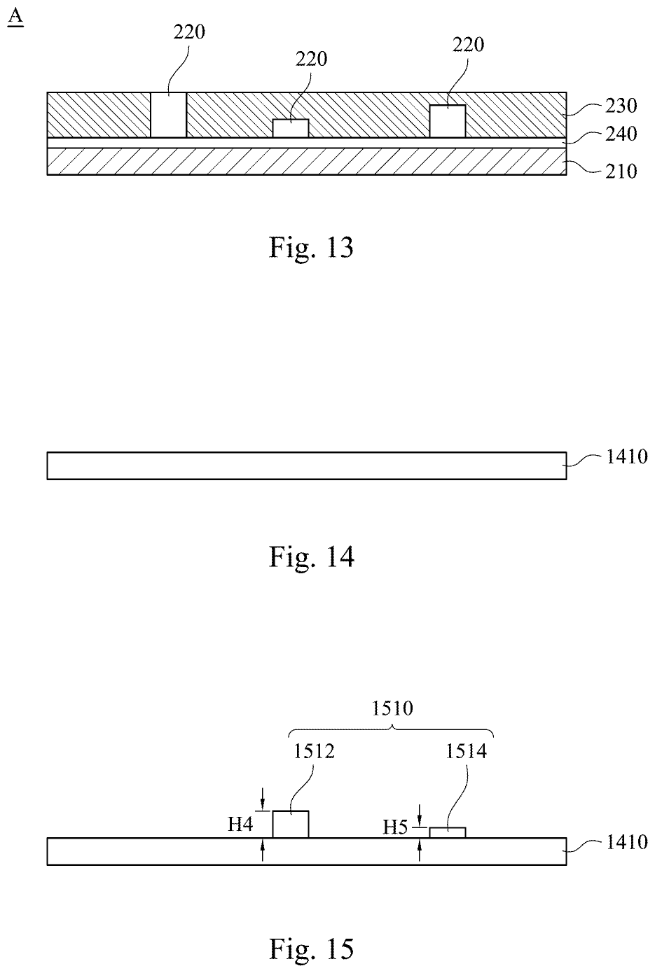

In operation 130, a liquid crystal polymer layer 230 is formed on the first substrate 210 and covers the first wire structure 220 to form the circuit board structure A as shown in FIG. 13. In various embodiments, the liquid crystal polymer layer 230 may include thermotropic liquid crystal polymers, the lyotropic liquid crystal polymers, or liquid crystal polymers having both thermotropic and lyotropic properties. More specifically, the liquid crystal polymers having both thermotropic and lyotropic properties have a melting point of thermotropic liquid crystal polymers and solubility of lyotropic liquid crystal polymers in a specific solvent. For example, thermotropic liquid crystal polymers may be purchased from supplier Kuraray; lyotropic liquid crystal polymers may be purchased from supplier Azotek; and liquid crystal polymers having both thermotropic and lyotropic properties may be purchased from supplier Azotek.

In one embodiment, if the thermotropic liquid crystal polymer is selected, the liquid crystal polymer layer 230 may be formed by film forming methods such as film blowing or casting. In one embodiment, if the lyotropic liquid crystal polymer is selected, the liquid crystal polymer layer 230 may be formed by film forming methods such as coating. In one embodiment, if the liquid crystal polymer having both thermotropic and lyotropic properties is selected, the liquid crystal polymer layer 230 may be formed by film forming methods such as casting or coating. It is noted that the liquid crystal polymer layer 230 formed by using the lyotropic liquid crystal polymer has no adhesion, so a bonding sheet is needed additionally to provide sufficient adhesion.

It can be understood that the liquid crystal polymer has the characteristics of low dielectric constant (Dk=2.9) and low dissipation factor (Df=0.001-0.002), which is suitable for high-frequency signal transmission, such as antennas. In addition to the excellent electrical characteristics of high-frequency signal transmission, the liquid crystal polymer also has low moisture absorption (the moisture absorption rate is about 0.01%-0.02%, which is 1/10 times that of the general PI substrate), thereby having good reliability. Therefore, the present disclosure preferably uses liquid crystal polymer as dielectric material of the circuit board structure.

FIGS. 14 and 15 are schematic cross-sectional views of each process stage in method 10 of manufacturing a circuit board structure B according to another embodiment of the present disclosure. Please refer to FIGS. 1 and 14 at the same time, in operation 140, a second substrate 1410 is provided. In some embodiments, the second substrate 1410 is a soft board including polyimide (PI), polytetrafluoroethylene (PTFE), liquid crystal polymaer (LCP), and a combination thereof. in other words, the second substrate 1410 is flexible.

Referring to FIGS. 1 and 15, in operation 150, a second wire structure 1510 is formed on the second substrate 1410. To be specific, the second wire structure 1510 includes a fourth wire 1512 having a fourth height H4. In some embodiments, the second wire structure 1510 further includes a fifth wire 1514 having a fifth height H5. In various embodiments, the second wire structure 1510 may include copper, aluminum, iron, silver, palladium, nickel, chromium, molybdenum, tungsten, zinc, manganese, cobalt, gold, tin, lead, stainless steel, or an alloy of at least two of the above metal materials. In various embodiments, the method of forming the second wire structure 1510 may be the same or similar to the method of forming the first wire structure 220, and will not repeated herein.

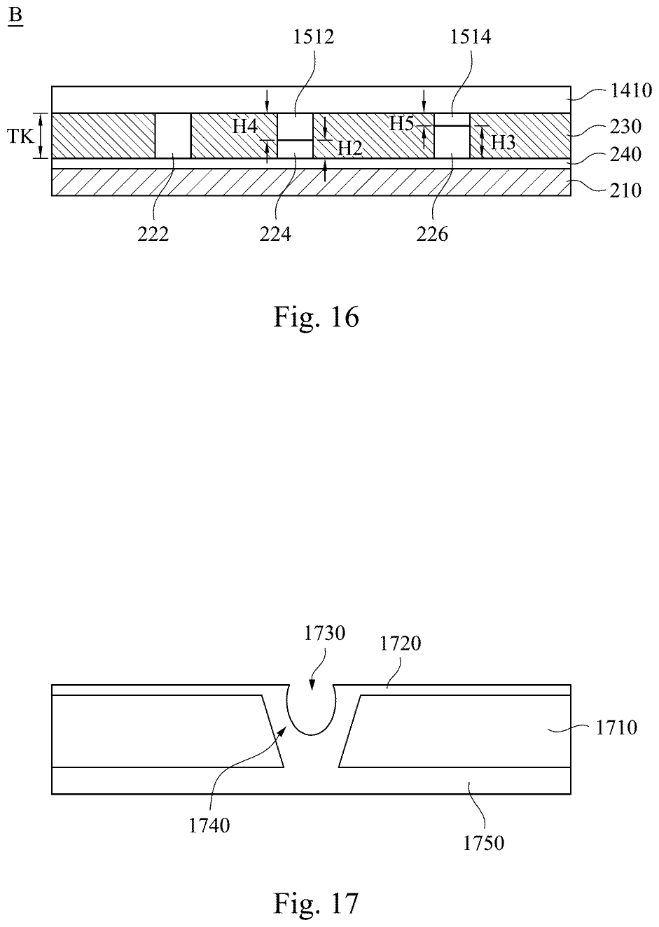

Referring to FIGS. 1 and 16, in operation 160, the second substrate 1410 is coupled to the first substrate 210 so that the fourth wire 1512 is embedded in the liquid crystal polymer layer 230 and in direct contact with the second wire 224 to form the circuit board structure B. In various embodiments, a sum of the fourth height H4 and the second height H2 is substantially equal to a thickness TK of the liquid crystal polymer layer 230. In various embodiments, the operation 160 is performed at a temperature between a liquid crystal polymer glass transition temperature and a liquid crystal polymer melting point.

In the embodiment of the second wire structure 1510 including the fifth wire 1514, after coupling the second substrate 1410 to the first substrate 210, the fifth wire 1514 is embedded in the liquid crystal polymer layer 230 and in direct contact with the third wire 226. In this embodiment, a sum of the fifth height H5 and the third height H3 is substantially equal to a thickness TK of the liquid crystal polymer layer 230.

FIG. 17 is a schematic cross-sectional view of a certain part of the conventional circuit board structure according to one comparative example of the present disclosure. Generally speaking, traditional circuit broads mostly use the built-up process to establish the circuit connection between the upper layer and the lower layer. The dielectric layer used in traditional circuit broads is usually a prepreg having a thickness ranges from about 75-300 um, and even more than 500 um. The wires 1720 and 1750 are respectively disposed on two opposite surfaces of the prepreg 1710, and the conductive via hole 1740 penetrates the prepreg 1710 and electrically connects to the wires 1720 and 1750, as shown in FIG. 17. Because the thickness of the prepreg is relatively thick, the conductive via hole 1740 formed by plating process will have serious dimple. This situation may be likely to cause out-gassing in the subsequence high-temperature process, thereby affecting the overall reliability of the circuit board.

Given above, compared with the traditional multilayer circuit board, the method of manufacturing the circuit board structure of the present disclosure may greatly reduce the number of layers required for the circuit board structure (i.e., reduce the overall thickness of the circuit board structure), thereby achieving the light and thin effect. And the method of manufacturing the circuit board structure of the present disclosure may also simplify the manufacturing process and reduce the cost. Moreover, the method of manufacturing the circuit board structure of the present disclosure may further avoid the problem of dimple caused by metal materials after filling the via hole, thereby reducing the risk of out-gassing during subsequent reflow testing. In addition, the method of manufacturing the circuit board structure of the present disclosure may also reduce the size of circuit wires and maximize the wiring density.

Although the present disclosure has been described in considerable detail with reference to certain embodiments thereof, other embodiments are possible. It will be apparent to those skilled in the art that various modifications and variations can be made to the structure of the present disclosure without departing from the scope or spirit of the disclosure. In view of the foregoing, it is intended that the present disclosure cover modifications and variations of this disclosure provided they fall within the scope of the following claims.

What is claimed is:

1. A method of manufacturing a circuit board structure, the method comprising:
(i) providing a first substrate;
(ii) forming a first wire structure on the first substrate, wherein the first wire structure comprises a first wire having a first height and a second wire having a second height, and the first height is greater than the second height; and
(iii) forming a liquid crystal polymer layer on the first substrate and covering the first wire structure.

2. The method of claim 1, further comprising forming a conductive layer between the first substrate and the first wire structure.

3. The method of claim 2, wherein the conductive layer is a patterned conductive layer or a conductive layer covering an entire upper surface of the first substrate.

4. The method of claim 1, wherein the operation (ii) comprises:
forming a first photoresist covering the first substrate;
forming a first opening and a second opening to expose a portion of the first substrate;
filling the first opening and the second opening with a first conductive material;
forming a second photoresist covering the first photoresist and the first conductive material;
forming a third opening to expose the first conductive material filled in the first opening;
filling the third opening with a second conductive material, wherein the second conductive material is in direct contact with the first conductive material in the first opening; and
removing the first photoresist and the second photoresist to form the first wire and the second wire.

5. The method of claim 4, wherein the first photoresist is a dry film photoresist or a liquid photoresist.

6. The method of claim 4, wherein the second photoresist is a dry film photoresist or a liquid photoresist.

7. The method of claim 1, wherein the first wire structure further comprises a third wire having a third height, the third height is smaller than the first height and greater than the second height.

8. The method of claim 7, wherein the operation (ii) comprises:
forming a first photoresist covering the first substrate;
forming a first opening, a second opening, and a third opening to expose a portion of the first substrate;
filling the first opening, the second opening, and the third opening with a first conductive material;
forming a second photoresist covering the first photoresist and the first conductive material;
forming a fourth opening and a fifth opening to respectively expose the first conductive material filled in the first opening and the first conductive material filled in the second opening;
filling the fourth opening and the fifth opening with a second conductive material, wherein the second conductive material is in direct contact with the first conductive material in the first opening and the second opening;
forming a third photoresist covering the second photoresist and the second conductive material;
forming a sixth opening to expose the second conductive material filled in the fourth opening;
filling the sixth opening with a third conductive material, wherein the third conductive material is in direct contact with the second conductive material in the fourth opening; and
removing the first photoresist, the second photoresist, and the third photoresist to form the first wire, the second wire, and the third wire.

9. The method of claim 1, further comprising:
(iv) providing a second substrate;
(v) forming a second wire structure on the second substrate, wherein the second wire structure comprises a fourth wire having a fourth height; and
(vi) coupling the second substrate to the first substrate so that the fourth wire is embedded in the liquid crystal polymer layer and in direct contact with the second wire.

10. The method of claim 9, wherein a sum of the fourth height and the second height is substantially equal to a thickness of the liquid crystal polymer layer.

11. The method of claim 9, wherein the operation (vi) is performed at a temperature between a liquid crystal polymer glass transition temperature and a liquid crystal polymer melting point.

12. A method of manufacturing a circuit board structure, the method comprising:
(i) providing a first substrate;
(ii) forming a first wire structure on the first substrate, wherein the first wire structure comprises a first wire having a first height, a second wire having a second height, and a third wire having a third height, the first height is greater than the second height, the third height is smaller than the first height and greater than the second height;
(iii) forming a liquid crystal polymer layer on the first substrate and covering the first wire structure;
(iv) providing a second substrate;
(v) forming a second wire structure on the second substrate, wherein the second wire structure comprises a fourth wire having a fourth height and a fifth wire having a fifth height; and
(vi) coupling the second substrate to the first substrate so that the fourth wire and the fifth wire are embedded in the liquid crystal polymer layer and respectively in direct contact with the second wire and the third wire.

13. The method of claim 12, wherein a sum of the fourth height and the second height is substantially equal to a thickness of the liquid crystal polymer layer.

14. The method of claim 12, wherein a sum of the fifth height and the third height is substantially equal to a thickness of the liquid crystal polymer layer.

15. The method of claim 12, wherein the operation (vi) is performed at a temperature between a liquid crystal polymer glass transition temperature and a liquid crystal polymer melting point.
